(19) United States
(12) Patent Application Publication
(10) Pub. No.: US 2024/0203927 A1
(43) Pub. Date: Jun. 20, 2024

(54) SEMICONDUCTOR DEVICE AND METHOD FOR MANUFACTURING SEMICONDUCTOR DEVICE

(71) Applicant: Kioxia Corporation, Tokyo (JP)

(72) Inventors: Satoshi TSUKIYAMA, Yokohama Kanagawa (JP); Satoru TAKAKU, Yokohama Kanagawa (JP)

(21) Appl. No.: 18/537,098

(22) Filed: Dec. 12, 2023

(30) Foreign Application Priority Data
Dec. 19, 2022 (JP) 2022-202095

(51) Int. Cl. H01L 23/00; H01L 23/29; H01L 23/31; H01L 25/065

(52) U.S. Cl. CPC H01L 24/32; H01L 23/293; H01L 23/3135; H01L 24/27; H01L 24/29; H01L 25/0657; H01L 23/3142; H01L 24/16; H01L 24/73; H01L 2224/16227; H01L 2224/27515; H01L 2224/2919; H01L 2224/32013; H01L 2224/32058; H01L 2224/32059; H01L 2224/32145; H01L 2224/73253; H01L 2225/06524; H01L 2924/18161

(57) ABSTRACT

According to one embodiment, a semiconductor device includes a wiring substrate with a first conductor portion and a second conductor portion on a first surface. A protective film is on the first surface of the wiring substrate. The protective film has a first opening exposing the first conductor portion and a second opening exposing the second conductor portion. A first electronic component is mounted to the wiring substrate. An electrode terminal of the first electronic component is connected to the first conductor portion through the first opening. A second electronic component is stacked on the first electronic component via an adhesive layer. A first resin layer is between the protective film and the first electronic component. A second resin layer is between the protective film and the adhesive layer, the second resin layer being outside the first electronic component in a plan view.

### CROSS-REFERENCE TO RELATED APPLICATION (S)

This application is based upon and claims the benefit of priority from Japanese Patent Application No. 2022-202095, filed Dec. 19, 2022, the entire contents of which are incorporated herein by reference.

### FIELD

Embodiments described herein relate generally to a semiconductor device and a method for manufacturing a semiconductor device.

### BACKGROUND

A semiconductor device including stacked electronic components is known. For example, a structure called a film-on-die (FOD) device includes stacked memory chips and a semiconductor chip, such as a controller, embedded in an adhesive layer such as a die attach film (DAF).

The semiconductor chip can be mounted on a wiring substrate by using flip-chip bonding via bumps or the like.

### BRIEF DESCRIPTION OF THE DRAWINGS

FIG. 1 is a cross-sectional view illustrating a schematic configuration of a semiconductor device according to a first embodiment.

FIGS. 2 to 6 illustrate aspects of a method for manufacturing a semiconductor device according to a first embodiment.

FIG. 7 is a schematic plan view illustrating aspects related to manufacture of a semiconductor device according to a first embodiment.

FIG. 8 is a cross-sectional view illustrating a schematic configuration of a semiconductor device according to a comparative example.

FIG. 9 is a cross-sectional view illustrating a schematic configuration of a semiconductor device according to a second embodiment.

### DETAILED DESCRIPTION

In a design in which a semiconductor chip is flip-chip bonded on a wiring substrate, it is possible to adopt a structure in which the semiconductor chip is embedded in an adhesive layer by applying the FOD structure. In this structure, a protective film called a solder resist layer is provided on the surface of the wiring substrate to which the semiconductor chip is bonded.

On the surface of the wiring substrate, an opening is provided in the protective film to permit connection to the internal wiring of the wiring substrate.

After a resin layer (called an underfill) is applied between the semiconductor chip and the wiring substrate so as to fill the space around the bonded portion, the semiconductor chip is covered with or embedded in a die attach film, and then electronic components, such as memory chips, are stacked on the die attach film.

In this design, a region of the opening in the protective film outside the semiconductor chip can be covered with the die attach film.

Embodiments relate to a semiconductor device having a configuration in which a film-on-die structure is applied to a wiring substrate that has a protective film with an opening and concern improving the reliability of wiring located within the opening in the protective film.

In general, according to one embodiment, semiconductor device includes a wiring substrate with a first conductor portion and a second conductor portion on a first surface. A protective film is on the first surface of the wiring substrate. The protective film has a first opening exposing the first conductor portion and a second opening exposing the second conductor portion. A first electronic component is mounted to the wiring substrate. An electrode terminal of the first electronic component is connected to the first conductor portion through the first opening. A second electronic component is stacked on the first electronic component via an adhesive layer. A first resin layer is between the protective film and the first electronic component. A second resin layer is between the protective film and the adhesive layer, the second resin layer being outside the first electronic component in a plan view.

Semiconductor devices according to certain example embodiments will be described with reference to the accompanying drawings. The present disclosure is not limited to these example embodiments. In description below, references to a vertical direction, such as upper or lower positions, are used for descriptive convenience to indicate relative positioning of various aspects in the drawings and such references may be unrelated to gravitational acceleration. The drawings are schematic or conceptual, and the depicted dimensions of each aspect or component, and dimensional relationships between aspects of components, is not necessarily the same as those in actuality. In the specification and the drawings, the same (or substantially the same) components or aspects are denoted by the same reference symbols, and the detailed descriptions of repeated components or aspects may be appropriately omitted from subsequent description.

### First Embodiment

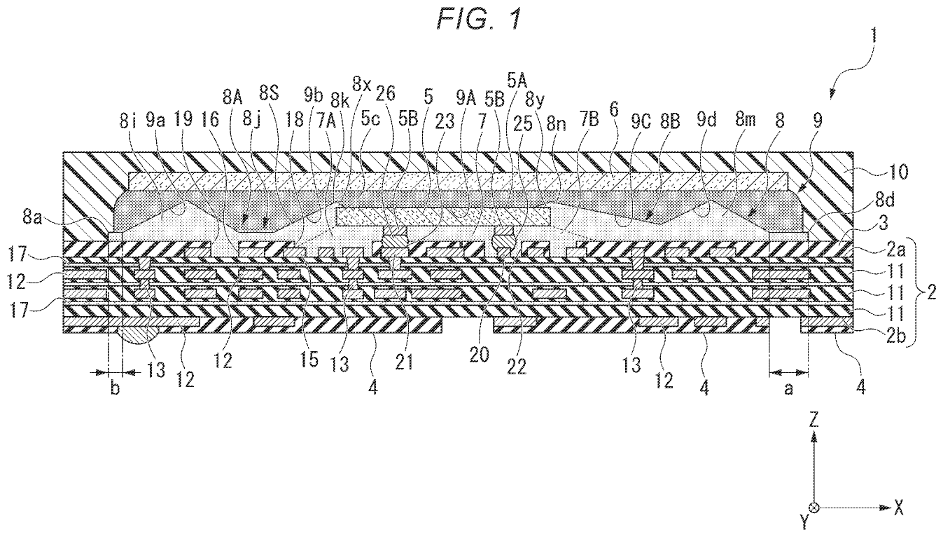

FIG. 1 is a cross-sectional view illustrating a schematic configuration of a semiconductor device 1 according to a first embodiment. The semiconductor device 1 includes a wiring substrate 2, protective films 3 and 4, a first electronic component 5, a second electronic component 6, a first resin layer 7, a second resin layer 8, an adhesive layer 9, and a sealing resin layer 10.

In the example illustrated in FIG. 1, only one second electronic component 6 is specifically depicted inside the sealing resin layer 10, but the depiction is representational and a plurality of second electronic components 6 may be stacked one-on-the-other in a thickness direction of the wiring substrate 2.

The semiconductor device 1 in this example has a ball grid array (BGA) semiconductor package with a film-on-die (FOD) structure.

The semiconductor device 1 can be a part of a variety of electronic equipment.

The electronic equipment may be a smartphone, a personal computer, a portable computer, a tablet, a mobile phone, a television receiver, a hard disk drive (HDD), a solid-state drive (SSD), a USB flash drive, an SD card, an eMMC®, a universal flash storage (UFS), a memory card, other storage devices, a wearable device, a smart speaker, a home appliance, and other electronic equipment.

In the present specification, an X axis, a Y axis, and a Z axis are defined as illustrated in FIG. 1. The X axis, the Y axis, and the Z axis are orthogonal to each other. The X axis is considered to be along the width direction of the semiconductor device 1. The Y axis is considered to be along the length direction of the semiconductor device 1. The Z axis is considered to be along the height (thickness) direction of the semiconductor device 1 or the wiring substrate 2.

The wiring substrate 2 is, for example, a printed circuit board (PCB). The wiring substrate 2 includes a front surface 2a (first surface) and a back surface 2b (second surface). The front surface 2a is a substantially flat surface facing a positive Z-axis direction (the direction indicated by the arrow of the Z axis), and the back surface 2b is a substantially flat surface facing a negative Z-axis direction. The first electronic component 5 (also referred to as a “chip”) is mounted on the front surface 2a of the wiring substrate 2.

The wiring substrate 2 includes a plurality of substrate plates 11 and a plurality of wiring layers 12, a plurality of vias 13, and the like.

The wiring substrate 2 is a multi-layered structure formed by bonding the plurality of substrate plates 11 via a substrate adhesive layer 17 such as a prepreg. Among the plurality of substrate plates 11, the surface of the uppermost substrate plate 11 (in the positive Z-axis direction) forms the front surface 2a of the wiring substrate 2, and the surface of the lowermost substrate plate 11 (in the negative Z-axis direction) forms the back surface 2b of the wiring substrate 2.

The front surface 2a of the wiring substrate 2 is covered with the protective film 3, and the back surface 2b is covered with the protective film 4. The protective film 3 and protective film 4 may be referred to as solder resist layers, solder resist films, or just “solder resist.” The protective film 3 is made of a resin such as acrylic polymer resin, an acrylate resin, or a mixed resin including acrylate resins, phenol resins, and/or epoxy resins.

The wiring substrate 2 has wiring layers 12 formed along the substrate plates 11, vias 13 penetrating through the substrate plates 11, and others including a wiring circuit provided with conductor portions 15, 16, 20, and 21. The wiring substrate 2 is, for example, an interposer substrate. Each of the conductor portions 15 and 16 illustrated in FIG. 1 shows a part of a narrow-pitch wiring in which a plurality of similar conductors are arranged in a Y-axis direction.

The conductor portions 20 and 21 are provided on the front surface 2a near a middle portion along the X-axis direction but spaced apart from each other in the X-axis direction. One opening 22 is formed in the protective film 3 around a conductor portion 20, and the conductor portion 20 is thus not covered by the protective film 3. Another opening 23 is formed in the protective film 3 around conductor portion 21, and thus the conductor portion 21 is not covered by the protective film 3.

The first electronic component 5 can be a packaged device, such as a controller chip. In the first electronic component 5, an integrated circuit, various circuit elements, and the like providing the functions of a controller or the like are accommodated inside a molded resin main body 5A. The molded resin main body 5A has a generally rectangular plate or chip shape. A plurality of electrode terminals 5B is formed on a bottom surface of the molded resin main body 5A. FIG. 1 illustrates two electrode terminals 5B spaced apart from each other in the X-axis direction.

One of the electrode terminals 5B is electrically connected to the conductor portion 20 via a bonding material 25 such as a solder bump. The other electrode terminal 5B is electrically connected to conductor portion 21 via a bonding material 26 such as a solder bump.

In the first electronic component 5 illustrated in FIG. 1, only two electrode terminals 5B are illustrated in FIG. 1 for the sake of simplification, but any number of electrode terminals 5B may be incorporated. In the first electronic component 5, typically a plurality of electrode terminals 5B will be provided arrayed in the X-axis direction and/or the Y-axis direction in FIG. 1. The number of the conductor portions 20 and 21 provided on the wiring substrate 2 also corresponds to the number of electrode terminals 5B.

Since the first electronic component 5 is provided above (the positive Z-axis direction side) the protective film 3 via the bonding materials 25 and 26, a gap is left between the protective film 3 and the first electronic component 5. This gap can be filled with the first resin layer 7. The first resin layer 7 comprises epoxy resin, for example. The first resin layer 7 may be referred to as an underfill resin.

The first resin layer 7 is formed so as to fill the gap between the protective film 3 and the bottom surface of the first electronic component 5. The first resin layer 7 slightly protrudes beyond the outer periphery of the first electronic component 5 in a plan view.

In the cross-section illustrated in FIG. 1, a first extended resin portion 7A extends on a negative X-axis direction side from the region directly between the protective film 3 and the first electronic component 5. A second extended resin portion 7B extends on a positive X-axis direction side from the region directly between the protective film 3 and the first electronic component 5.

The first extended resin portion 7A has a width (width in the X-axis direction) slightly greater than the width (width in the X-axis direction) of the second extended resin portion 7B. An extended resin portion of the first resin layer 7 also extends on a positive Y-axis direction side of the region directly between the protective film 3 and the first electronic component 5. Similarly, another extended resin portion of the first resin layer 7 extends on a negative Y-axis direction side of the region directly between the protective film 3 and the first electronic component 5. These extended resin portions can be formed to have lengths in the Y-axis direction that are approximately the same as the width (width in the X-axis direction) of the second extended resin portion 7B.

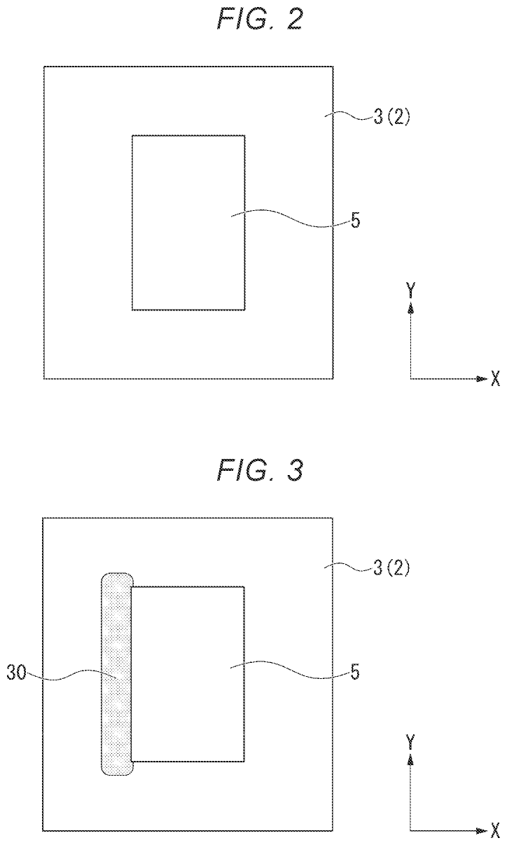

These extended resin portions of resin layer 7 will also be described by reference to FIGS. 2 to 6.

The second resin layer 8 surrounds the outer periphery of the first resin layer 7. The second resin layer 8 and the first resin layer 7 may be integrated with each other to be a continuous material. The second resin layer 8 is formed to fill the gap between the adhesive layer 9 and the protective film 3. The second resin layer 8 also surrounds the outer peripheries of the first electronic component 5 and the first resin layer 7.

The second electronic component 6 is a packaged semiconductor component having a rectangular plate shape in a plan view. The second electronic component 6 may be a memory chip or the like. The adhesive layer 9 is formed as a film on a bottom surface of the second electronic component 6. The second electronic component 6 can have a width and a length greater than the width and the length of the first electronic component 5. The adhesive layer 9 is formed to have a width and a length slightly greater than the width and the length of the second electronic component 6. Thus, the width and the length of the adhesive layer 9 are larger than the first electronic component 5 and the second electronic component 6.

In the example of FIG. 1, the adhesive layer 9 has a width several times larger than the width of the first electronic component 5. The length of the adhesive layer 9 in the Y direction is also several times larger than the length of the first electronic component 5 in the Y direction.

The adhesive layer 9 is, for example, a die attach film (DAF) comprising acrylic resin and epoxy resin. A die attach film can also be called a die bonding film. The adhesive layer 9 is a pre-structured film such as an adhesive tape or the like.

The second resin layer 8 is, for example, made of the same type resin material as the first resin layer 7. The second resin layer 8 in some examples may be a same type resin material as the first resin layer 7, but the second resin layer 8 may have a different concentration of a filler material, e.g., inorganic oxide particles, or other components therein.

In some examples, the second resin layer 8 may be a different resin composition from the first resin layer 7.

For example, it is preferable that the first resin layer 7 and the second resin layer 8 both comprise an epoxy resin as a main component. However, the first resin layer 7 and the second resin layer 8 may still differ in other components provided for hardening, thermosetting, curing, and the like. In addition, it may be preferable that the first resin layer 7 and the second resin layer 8 are a thermosetting resin not including an acrylic resin such as acrylic polymer.

In the protective film 3, openings are formed at a plurality of locations around the first electronic component 5. In FIG. 1, the opening 18 (second opening 18) in the protective film 3 is opens on the conductor portion 15 at position outside of the first electronic component 5.

On the wiring substrate 2, it is necessary to provide a plating electrode wiring for forming a corrosion-resistant layer, such as a gold-plated layer, on exposed terminals and connected conductor portions of the wiring circuit by plating or the like. After a gold-plated layer is formed on the exposed terminals and the connected conductor portions of the wiring substrate 2 by use of the plating electrode wiring, the plating electrode wiring can be removed by an etching treatment. For the etching treatment, the protective film 3 present at the opening 18 can be removed by laser or the like, and the plating electrode wiring under the protective film 3 is removed by etching, laser, or the like.

The conductor portion 15 provided in the second opening 18 (as illustrated in FIG. 1) is a conductor portion remaining in the second opening 18 after the plating electrode wiring has been removed by the etching treatment.

The second opening 18 is formed from a position near the conductor portion 21 to a position outside in the negative X-axis direction from the region in which the first electronic component 5 is mounted. In the cross-sectional structure illustrated in FIG. 1, an end of the second opening 18 in the negative X-axis direction is located at the conductor portion 15 provided at a position slightly away from an end of the first electronic component 5 in the negative X-axis direction. The conductor portion 15 is covered with the protective film 3 for approximately half its width in the X-axis direction, and the other half is located in the second opening 18 (uncovered). Since the second opening 18 is filled with the first extended resin portion 7A, about a half of the conductor portion 15 in the X-axis direction is covered with the first resin layer 7. In addition, the boundary between the first resin layer 7 and the second resin layer 8 is located near the conductor portion 15.

An opening 19 is also formed at a position further away to the negative X-axis direction side from the position at which the conductor portion 15 is provided, and a conductor portion 16 is provided inside the opening 19.

The conductor portion 16 is also a conductor portion remaining inside the opening 19 after the plating electrode wiring has been removed by the etching treatment described above.

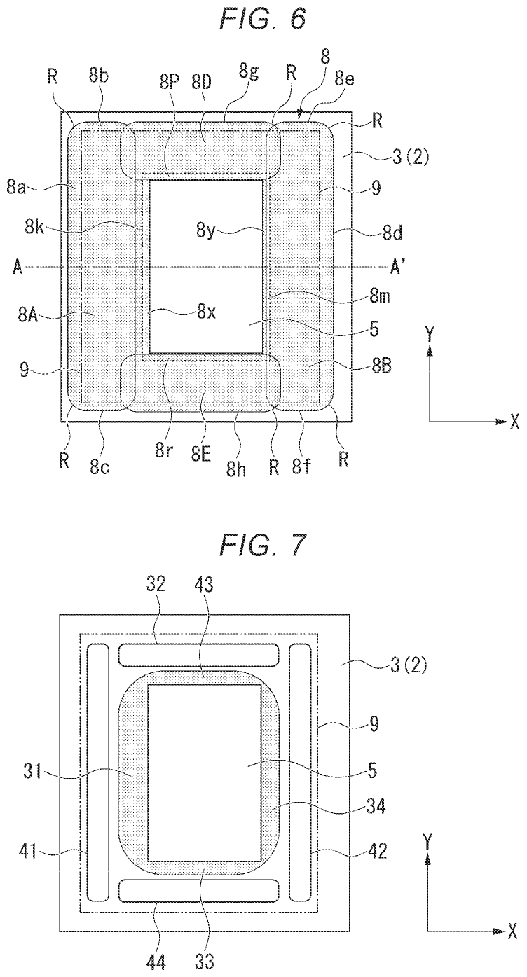

FIG. 6 illustrates an overview of the positional relationship between the first electronic component 5 and the second resin layer 8 in a plane view. In FIG. 6, the outline position of the outer circumferential edge of the adhesive layer 9 is indicated by a rectangular dash-double-dotted line, and the outline of the outer circumferential edge of the first electronic component 5 is indicated by a dotted line.

As illustrated in FIG. 6, the second resin layer 8 surrounds the four sides of the first electronic component 5 in a plan view. The second resin layer 8 thus forms a rectangular frame shape or rectangular ring shape.

The second resin layer 8 includes a first edge portion 8A located on the left side in FIG. 6 (on the negative X-axis direction side), a second edge portion 8B located on the right side (on the positive X-axis direction side), and a third edge portion 8D and a fourth edge portion 8E connecting the first edge portion 8A and the second edge portion 8B.

The first edge portion 8A is a resin layer extending in the Y-axis direction beyond the edges of the first electronic component 5 on one side of the first electronic component 5.

The second edge portion 8B is a resin layer extending in the Y-axis direction beyond the edges of the first electronic component 5 on another side of the first electronic component.

The third edge portion 8D is a resin layer extending in the X-axis direction so as to connect an end of the first edge portion 8A and an end of the second edge portion 8B.

The fourth edge portion 8E is a resin layer extending in the X-axis direction so as to connect an end of the first edge portion 8A and an end of the second edge portion 8B.

The portions of the second resin layer 8 form a rectangular frame shape in a plan view with the first edge portion 8A, the second edge portion 8B, the third edge portion 8D, and the fourth edge portion 8E.

As illustrated in FIG. 6, a round R is formed at each corner of the first edge portion 8A, the second edge portion 8B, the third edge portion 8D, and the fourth edge portion 8E.

The cross-section along the line A-A′ in FIG. 6 corresponds to the cross-section in FIG. 1.

The end edge of the first edge portion 8A in the negative X-axis direction includes a first extended portion 8a that slightly protrudes outward from the end edge of the adhesive layer 9. The end edge of the first edge portion 8A in the positive Y-axis direction includes a second extended portion 8b that slightly protrudes outward from the end edge of the adhesive layer 9. The end edge of the first edge portion 8A in the negative Y-axis direction includes a third extended portion 8c that slightly protrudes outward from the end edge of the adhesive layer 9. In the cross-section in FIG. 1, among these extended portions, only the first extended portion 8a is specifically illustrated.

The end edge of the second edge portion 8B in the positive X-axis direction includes a fourth extended portion 8d that slightly protrudes outward from the end edge of the adhesive layer 9. The end edge of the second edge portion 8B in the positive Y-axis direction includes a fifth extended portion 8e that slightly protrudes outward from the end edge of the adhesive layer 9. The end edge of the second edge portion 8B in the negative Y-axis direction includes a sixth extended portion 8f that slightly protrudes outward from the end edge of the adhesive layer 9. In the cross-section in FIG. 1, among these extended portions, only the fourth extended portion 8d is specifically illustrated.

The end edge of the third edge portion 8D in the positive Y-axis direction includes a seventh extended portion 8g that slightly protrudes outward from the end edge of the adhesive layer 9.

The end edge of the fourth edge portion 8E in the negative Y-axis direction includes an eighth extended portion 8h that slightly protrudes outward from the end edge of the adhesive layer 9.

As illustrated in FIG. 6, the first edge portion 8A, the second edge portion 8B, the third edge portion 8D, and the fourth edge portion 8E form a rectangular frame shape in a plan view. Each of the extended portions (first extended portion 8a to eighth extended portion 8h) is provided at a position protruding outside the dash-double-dot line that indicates the outer circumferential outline of the adhesive layer 9 in FIG. 6.

As illustrated in the cross-section in FIG. 1, in the first edge portion 8A, a first ridge 8i having a mountain shape (peaked shape) projecting in the positive Z-axis direction is formed along the Y-axis direction at a position near the first extended portion 8a. In other words, the first ridge 8i protrudes toward the adhesive layer side. In the first edge portion 8A, a connection portion 8j having a flat shape that is an extension of the base portion of the first ridge 8i is formed towards the center in the X-axis direction. In the first edge portion 8A, a second ridge 8k having a mountain shape (peaked shape) projecting in the positive Z-axis direction is formed along the Y-axis direction at an end of the first edge portion 8A in the positive X-axis direction.

A top portion 8x of the second ridge 8k is a covering portion that covers an end edge 5c of the first electronic component 5. A portion of top portion 8x may be on the upper surface of the first electronic component 5.

The second ridge 8k is a resin layer located above the first extended resin portion 7A such that the second ridge 8k at least partially covers the end edge 5c of the first electronic component 5.

A base portion of the second ridge 8k is formed with an inclined surface 8S that angles downward towards the protective film 3 side at a predetermined inclination angle. A part of the second ridge 8k on the positive X-axis direction side is occupied by the end edge 5c of the first electronic component 5.

The cross-sectional shape of the second edge portion 8B illustrated in FIG. 1 is similar though not identical to the cross-sectional shape of the first edge portion 8A. The second edge portion 8B includes a third ridge 8m having a cross-sectional shape similar to the first ridge 8i and a fourth ridge 8n having a cross-sectional shape similar to the second ridge 8k. The cross-sectional shape of the third ridge 8m is similar to the cross-sectional shape of the first ridge 8i, and the height of the third ridge 8m and the height of the first ridge 8i are almost the same. The third ridge 8m extends along the second edge portion 8B in the Y-axis direction.

The third ridge 8m is formed at a position more inward from the outer edge of the adhesive layer 9 than is the first ridge 8i.

A distance from an end of the fourth extended portion 8d to a base portion of the third ridge 8m is denoted as a distance a. A distance from an end of the first extended portion 8a to a base portion of the first ridge 8i is denoted as a distance b. Then, the relationship between the distance a and the distance b is set to be distance a>distance b.

In the cross-sectional structure illustrated in FIG. 1, the base portion of the third ridge 8m and a base portion of the fourth ridge 8n are formed such that the inclined portions of the base portions are continuous with each other and no flat portion is formed therebetween. In this respect, the cross-sectional shape of the first edge portion 8A and the cross-sectional shape of the second edge portion 8B are thus slightly different from each other.

In addition, the inclination angle of the base portion of the fourth ridge 8n on the positive X-axis direction side is less than the inclination angle of the base portion of the second ridge 8k on the negative X-axis direction side.

A top portion 8y of the fourth ridge 8n is a covering portion that covers the end edge 5c of the first electronic component 5. A portion of top portion 8y may be on the upper surface of the first electronic component 5.

A part of the fourth ridge 8n is occupied by the end edge of the first electronic component 5.

The cross-sectional shapes of the third edge portion 8D and the fourth edge portion 8E are substantially equivalent to the cross-sectional shape of the second edge portion 8B. Thus, each of the third edge portion 8D and the fourth edge portion 8E is formed with ridges such as depicted in FIG. 1.

FIG. 6 illustrates a top portion (covering portion) 8p of a ridge that is formed at the third edge portion 8D and covers an end edge of the first electronic component 5 in the positive Y-axis direction over a certain width. FIG. 6 illustrates a top portion (covering portion) 8r of a ridge that is formed at the fourth edge portion 8E and covers an end edge of the first electronic component 5 in the negative Y-axis direction over a predetermined width.

The bottom surface of the adhesive layer 9 is adhered to the top surfaces of the first electronic component 5, the first resin layer 7, and the second resin layer 8. A flat surface 9A is formed at the center of the bottom surface of the adhesive layer 9, and the flat surface 9A covers the top surface of the first electronic component 5.

On the bottom surface side of the adhesive layer 9, a recess 9a covering the first ridge 8i and a recess 9b covering the second ridge 8k are formed, and a recess 9d covering the third ridge 8m and a recess 9c covering the fourth ridge 8n are formed. A recess covering the ridge formed at the third edge portion 8D and a recess covering the ridge formed at the fourth edge portion 8E are also formed on the bottom surface side of the adhesive layer 9. Thus, the adhesive layer 9 adheres to the top surface of the first electronic component 5, the top surface of the first resin layer 7, and the top surface of the second resin layer 8 without leaving a gap therebetween.

### Method for Manufacturing Semiconductor Device

The configuration in which the ridges 8i, 8k, 8m, and 8n are formed in the second resin layer 8 and the adhesive layer 9 adheres to the ridges without a gap is described below with reference to FIGS. 2 to 6.

FIG. 2 is a schematic plan view illustrating a state in which the first electronic component 5 has been mounted on the top surface of the wiring substrate 2.

In FIG. 2 the electrode terminals 5B of the first electronic component 5 have been electrically bonded to the conductor portions 20 and 21 of the wiring substrate 2 via the bonding materials 25 and 26 (e.g., solder balls). In this state, a gap (space portion) is left between the protective film 3 of the wiring substrate 2 and the first electronic component 5.

After the first electronic component 5 has been mounted in this manner, an uncured resin for forming the first resin layer 7 is applied in a predetermined area and amount along an outside edge of the first electronic component 5 as illustrated in FIG. 3. This uncured resin application process can be performed by using an application device such as a dispenser (liquid resin dispenser).

By applying uncured resin, it is possible to form a first coating layer 30 as illustrated in FIG. 3. The first coating layer 30 is formed such that an end of the first coating layer 30 in the positive X-axis direction overlaps the gap between the protective film 3 and the first electronic component 5 over a predetermined width.

When the first coating layer 30 is formed in this way, the uncured resin gradually and automatically fills into the gap (the space portion) between the protective film 3 and the first electronic component 5 by a capillary action, and thus the gap can be filled with the uncured resin at this time.

In order to sufficiently fill the gap with the uncured resin, the coating thickness of the first coating layer 30 is formed to be sufficiently greater than the height of the gap so the uncured resin can be pulled into the gap by the capillary action in sufficient amount. The uncured resin has an appropriate viscosity such that when applied thickly as described above, the cross-sectional shape of the uncured resin will have a well-formed peaked mountain shape such as a Konide type.

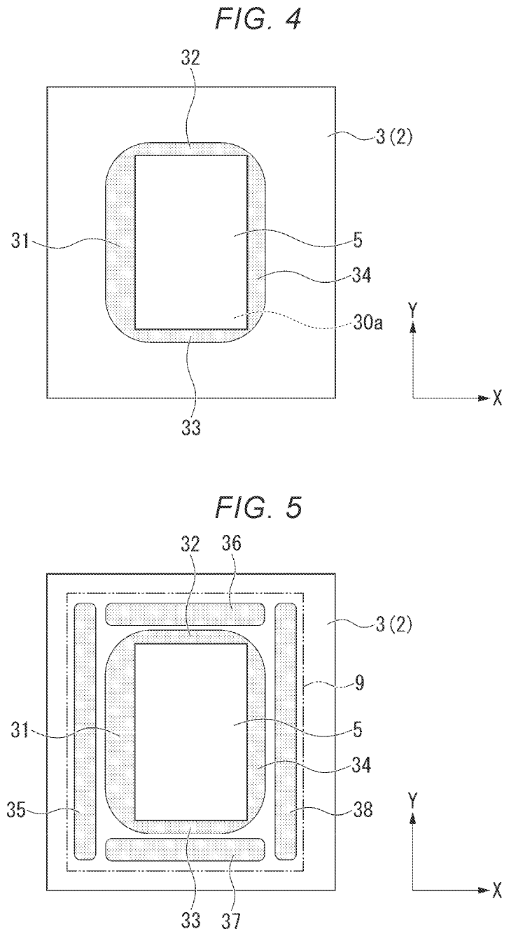

FIG. 4 illustrates a state after the gap between the protective film 3 and the first electronic component 5 has been filled with the uncured resin material. In filling the gap, the uncured resin will also protrude some amount from the circumferential edges of the first electronic component 5 as depicted in the plan view in FIG. 4.

To provide the uncured resin in this manner, the amount of the uncured resin necessary to be applied in the forming of the first coating layer 30 (as illustrated in FIG. 3) may be estimated, calculated, or determined in advance.

Since the uncured resin forming the first coating layer 30 fills the gap by capillary action without intervention, the state illustrated in FIG. 4 can be reliably obtained by application of the appropriate amount of resin material in the initial formation the first coating layer 30.

In the state illustrated in FIG. 4, uncured filled resin layer 30a between the protective film 3 and the first electronic component 5 forms a first extended resin layer 31 having a wide width on the negative X-axis direction side (left page side in FIG. 4) of the first electronic component 5. A second extended resin layer 32 having a width narrower than the first extended resin layer 31 is formed on the positive Y-axis direction side (upper page side in FIG. 4) of the first electronic component 5. A third extended resin layer 33 having a width narrower than the first extended resin layer 31 on the negative Y-axis direction side (lower page side in FIG. 4) of the first electronic component 5. A fourth extended resin layer 34 having a width narrower than the first extended resin layer 31 is formed on the positive X-axis direction side (right page side in FIG. 4) of the first electronic component 5.

The first extended resin layer 31 is formed from the first coating layer 30, and thus has the largest width. The second extended resin layer 32, the third extended resin layer 33, and the fourth extended resin layer 34 are formed by wet-spreading of the uncured resin into the gap by capillary action. Since the force of the wet-spreading is not so strong, the second to fourth extended resin layers 32 to 34 have widths narrower than the first extended resin layer 31.

After the respective uncured resin layers are formed as illustrated in FIG. 4, a second coating layer 35 for forming the second resin layer 8 is formed using the uncured resin on the left side (the negative X-axis direction side) of the first extended resin layer 31 as illustrated in FIG. 5 by using an application device such as a dispenser. The second coating layer 35 is formed in a strip shape having a predetermined width in the X-axis direction along the Y-axis direction.

The length in the Y-axis direction of the second coating layer 35 is formed to be close to the length in the Y-axis direction of the dash-double-dot line that indicates the outer circumferential outline of the adhesive layer 9 illustrated in FIG. 5. Since the second coating layer 35 is made of the uncured resin layer having an appropriate viscosity, the second coating layer 35 is formed in a raised shape such as a mountain shape in a cross-sectional view on the wiring substrate 2 (to be precise, on the protective film 3). The second coating layer 35 is formed thickly enough to wet-spread so as to be integrated with the first extended resin layer 31 in a later process. For example, the second coating layer 35 is applied thickly to have a mountain shape in a cross-sectional view.

Next, a third coating layer 36 for forming the second resin layer 8 is formed into a strip shape in a plan view using uncured resin on the positive Y-axis direction side (upper side in FIG. 4) of the second extended resin layer 32. Similarly, a fourth coating layer 37 and a fifth coating layer 38 for forming the second resin layer 8 are respectively formed into a strip shape in a plan view using uncured resin. Forming of these coating layers can be performed by using an application device such as a dispenser in the same way as in forming the second coating layer 35.

The order of forming the second coating layer 35 to the fifth coating layer 38 is not limited to the order described above, and any coating layer may be formed first, or the four coating layers may be formed at the same time.

Since all the second coating layer 35, the third coating layer 36, the fourth coating layer 37, the fifth coating layer 38 are made of the uncured resin having an appropriate viscosity, these coating layers are formed in a raised shape such as a mountain shape in a cross-sectional view on the protective film 3.

After a lapse of a certain time from the forming of the respective coating layers, the coating layers will gradually wet-spread along the protective film 3 in accordance with the viscosity of each coating layer. As a result, the second coating layer 35, the third coating layer 36, the fourth coating layer 37, and the fifth coating layer 38 are eventually integrated (melded) with the first extended resin layer 31, the second extended resin layer 32, the third extended resin layer 33, and the fourth extended resin layer 34, respectively. In the wet-spread state, the uncured resin still maintains a raised state so as to have a convex ridge in a cross-sectional view at this time.

Thereafter, the filled resin layer between the protective film 3 and the first electronic component 5, the extended resin layers 31 to 34, and the coating layers 35 to 38 are cured by being heated to obtain the structure illustrated in FIG. 6.

That is, the first edge portion 8A, the second edge portion 8B, the third edge portion 8D, and the fourth edge portion 8E can be formed to surround the circumference of the first electronic component 5. The first ridge 8i and the second ridge 8k are formed at the first edge portion 8A, and the third ridge 8m and the fourth ridge 8n are formed at the second edge portion 8B. Ridges are also formed at the third edge portion 8D and the fourth edge portion 8E. In FIG. 6, illustrations of the respective ridges are omitted.

It should be noted that, after the coating layers 35 to 38 are applied, a pressing process may be performed such that the coating layers 35 to 38 are pressed from the positive Z-axis direction side using an appropriate jig or template to help wet-spread the coating layers 35 to 38.

After the first edge portion 8A, the second edge portion 8B, the third edge portion 8D, and the fourth edge portion 8E as illustrated in FIG. 6 are formed, the second electronic component 6 including an adhesive layer 9 that initially has a flat even thickness is prepared.

This initially flat adhesive layer 9 is caused to approach the first edge portion 8A, the second edge portion 8B, the third edge portion 8D, and the fourth edge portion 8E from the positive Z-axis direction side (upper side) and pressed against these edge portions.

By pressing, the initially flat adhesive layer 9 deforms along the first edge portion 8A, the second edge portion 8B, the third edge portion 8D, and the fourth edge portion 8E and adheres and conforms to these edge portions.

As a result of the above-described process, the second electronic component 6 can be attached to the wiring substrate 2 by using the adhesive layer 9 that adheres to the first ridge 8i, the second ridge 8k, the third ridge 8m, and the fourth ridge 8n as illustrated in the cross-section in FIG. 1.

After the second electronic component 6 is mounted on the wiring substrate 2, the terminals of the second electronic component 6 can be connected to the terminals of the wiring substrate 2 by a method such as wire bonding. Thereafter, the configuration illustrated in FIG. 1 can be obtained by providing the sealing resin layer 10.

According to the semiconductor device 1 as illustrated in FIG. 1, the adhesive layer 9 does not directly contact the protective film 3, and the first resin layer 7 and the second resin layer 8 are everywhere interposed between the adhesive layer 9 and the protective film 3.

Thus, in the wiring substrate 2, the opening 18 and the opening 19 of the protective film 3 are filled with the first resin layer 7 or the second resin layer 8. Accordingly, the conductor portions 15 and 16 in these second openings 18 and 19 are covered with the first resin layer 7 or the second resin layer 8.

Each of the first resin layer 7 and the second resin layer 8 comprises epoxy resin or is a resin containing epoxy resin as a main component, and these resin layers 7 and 8 are thus less likely to emit chlorine ions even when subjected to heating.

On the other hand, the adhesive layer 9 has a film form and comprises acrylic resin, and the resin forming the protective film 3 also comprises acrylic or acrylate resin. Thus, the adhesive layer 9 and the protective film 3 each generate a small amount of chlorine ions when heated. When the conductor portions 15 and 16 exist near an area where the adhesive layer 9 and the protective film 3 are in contact with each other, the resin forming the protective film 3 is likely to be hydrolyzed due to a synergistic effect of chlorine ions generated from the both layers by heating.

With the cross-sectional structure illustrated in FIG. 1, the resin forming the protective film 3 is less likely to be hydrolyzed even in an accelerated lifetime test such as a highly accelerated temperature and humidity stress test (HAST) performed under a high-temperature and high-humidity environment that would be atypical for normal device operations.

Thus, the semiconductor device 1 having an excellent durability can be provided.

FIG. 7 illustrates a configuration example in which a first recess 41, a second recess 42, a third recess 43, and a fourth recess 44, each having a shallow groove shape, are provided at positions corresponding to application positions at which the second coating layer 35, the third coating layer 36, the fourth coating layer 37, and the fifth coating layer 38 are applied on the protective film 3 as illustrated in FIG. 5.

For applying the uncured resin layers on the protective film 3 using an application device such as a liquid dispenser, the first recess 41, the second recess 42, the third recess 43, and the fourth recess 44 can be provided to serve as marks for applying the uncured resin materials at accurate positions.

In addition, by providing these recesses, the application amount of the uncured resin can be accurately adjusted, making it easier to wet-spread the uncured resin layers into a stable shape such as illustrated in FIG. 6.

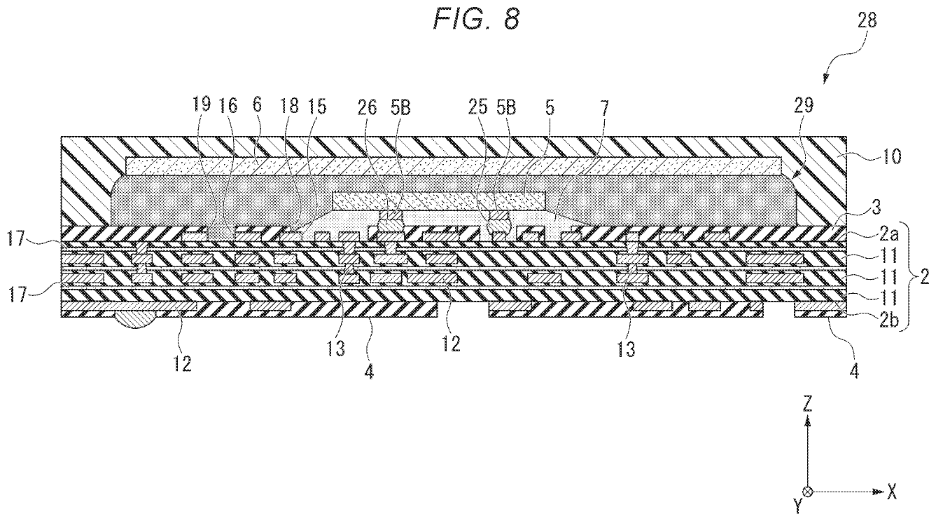

FIG. 8 illustrates a semiconductor device 28 having a comparative example structure in which the first resin layer 7 is provided between the first electronic component 5 and the protective film 3, but in which the second resin layer 8 is omitted. A portion corresponding to where the second resin layer 8 would be provided in the structure illustrated in FIG. 1 is occupied by an adhesive layer 29.

Since no second resin layer 8 is provided in this comparative example, the adhesive layer 29 is provided in direct contact with the surface of the protective film 3, and about a half of the conductor portion 15 and the opening 19 are filled with this adhesive layer 29. The conductor portion 15 is located at a boundary of the first resin layer 7, the protective film 3, and the adhesive layer 29. Thus, the boundary between the adhesive layer 29 and the protective film 3 is located near the conductor portion 15. The boundary between the adhesive layer 29 and the protective film 3 is located near the conductor portion 16.

When the comparative example structure illustrated in FIG. 8 is subjected to heating over time, chlorine ions emitted from the adhesive layer 29 and chlorine ions emitted from the protective film 3 are discharged near the conductor portions 15 and 16.

Thus, resin decomposition in the protective film 3 is likely to be accelerated around the conductor portions 15 and 16.

On the other hand, in the structure illustrated in FIG. 1, the first resin layer 7 and the second resin layer 8, which contain epoxy resin or are mainly made of epoxy resin, and the protective film 3 are near the conductor portion 15 without the adhesive layer 9 nearby.

Even if a small amount of chlorine ions is emitted from the protective film 3, resin decomposition is not accelerated in the protective film 3 near the conductor portion 15 because the adhesive layer 9 is located at a distance away from the conductor portion 15. In addition, only the protective film 3 is present near the conductor portion 16. Without the presence of the adhesive layer 9, resin decomposition is not accelerated in the protective film 3 near conductor portion 16. As a result, the semiconductor device 1 has excellent durability.

### Second Embodiment

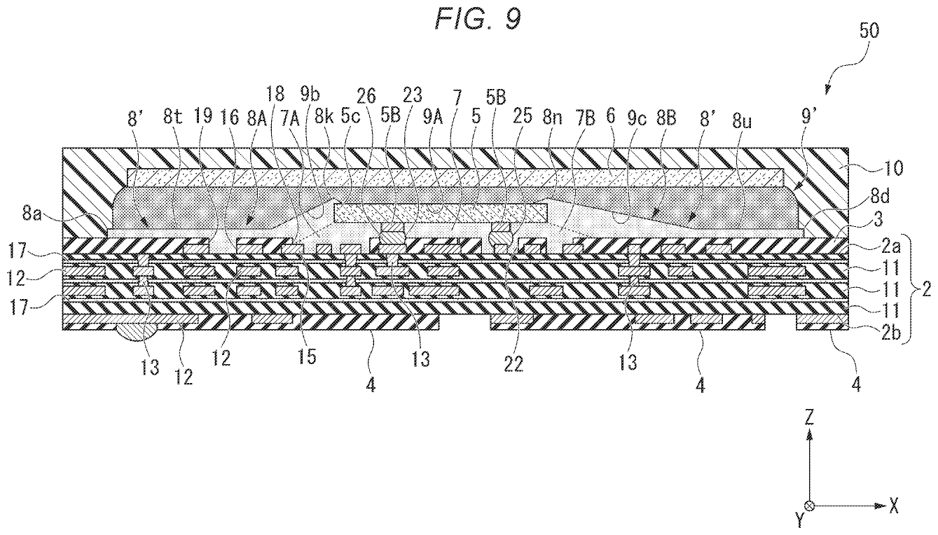

FIG. 9 is a cross-sectional view illustrating a semiconductor device 50 according to a second embodiment.

In the second embodiment, the wiring substrate 2, the first electronic component 5, the second electronic component 6, the first resin layer 7, and the sealing resin layer 10 are substantially similar to those aspects described in the first embodiment.

In FIG. 9, the electrode terminals 5B of the first electronic component 5 are bonded to the wiring substrate 2 via the bonding materials 25 and 26 such as solder balls as in the first embodiment.

In FIG. 9, a second resin layer 8′ is provided around the first resin layer 7. This configuration differs from the first embodiment.

In the second resin layer 8′, the first ridge 8i and the third ridge 8m present in the second resin layer 8 of the first embodiment are omitted. A flat portion 8t is formed where the first ridge 8i was formed, and a flat portion 8u is formed where the third ridge 8m was formed.

The resin forming the second resin layer 8′ can be the same as used for the second resin layer 8.

In the second resin layer 8′, the second ridge 8k covers the end edge 5c of the first electronic component 5 and the fourth ridge 8n covers the opposite end edge of the first electronic component 5 in a manner similar to the first embodiment for the second resin layer 8.

In the second resin layer 8′, the flat portion 8t is formed on the negative X-axis direction side of the second ridge 8k, and the flat portion 8u is formed on the positive X-axis direction side of the fourth ridge 8n. The first extended portion 8a is formed at an end of the flat portion 8t in the negative X-axis direction, and the fourth extended portion 8d is formed at an end of the flat portion 8u in the positive X-axis direction.

In the second ridge 8k formed at the first edge portion 8A, the inclination angle of a base portion on the negative X-axis direction side can be the same as that of the second ridge 8k in the first embodiment. Accordingly, the base portion of the second ridge 8k is less than half the width of the first edge portion 8A in the X-axis direction.

In the fourth ridge 8n formed at the second edge portion 8B, the inclination angle of a base portion on the positive X-axis direction side can be the same as the inclination angle of the base portion of the fourth ridge 8n in the first embodiment.

In the second embodiment, the first resin layer 7 and the second resin layer 8′ are interposed between an adhesive layer 9′ and the protective film 3 of the wiring substrate 2, and thus a highly reliable wiring structure can be obtained as in the structure of the first embodiment.

That is, the opening 18 is filled with the first resin layer 7, and the opening 19 is filled with the second resin layer 8′. Thus, the adhesive layer 9′ does not exist in the vicinity of the conductor portion 15 located under the opening 18 and in the vicinity of the conductor portion 16 located under the opening 19.

Accordingly, in the second embodiment, the protective film 3 is less likely to be hydrolyzed even in an accelerated test such as a HAST.

In forming the second coating layer 35, the third coating layer 36, the fourth coating layer 37, and the fifth coating layer 38 as illustrated in FIG. 5, the structure of the second embodiment can be obtained by setting the application thicknesses of the coating layers to be thinner than those used in the first embodiment.

### Other Embodiments

(a) In the first embodiment, either or both of the first resin layer 7 and the second resin layer 8 may cover the top surface of the first electronic component 5 in whole or in part. Even in that case, similar effects as in the first embodiment can be obtained. This configuration can be obtained, for example, by further dispensing the second resin layer 8 onto the top surface of the first electronic component 5 after FIG. 6. Alternatively, this configuration can be obtained by dispensing the first coating layer 30 in a large amount enough for the coating layer 30 to reach the top surface of the first electronic component 5 in a state of FIG. 3. This configuration can be also obtained by a variety of other methods.
(b) In the first embodiment, the second resin layer 8 protrudes beyond the adhesive layer 9. However, the present disclosure is not limited to this, and the first resin layer 7 or the second resin layer 8 only needs to cover such a range that the second opening 19 is filled prior to application of the adhesive layer 9. Even in this case, similar effects as in the first embodiment can be obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a wiring substrate with a first conductor portion and a second conductor portion on a first surface;
a protective film on the first surface of the wiring substrate, the protective film including a first opening exposing the first conductor portion and a second opening exposing the second conductor portion;
a first electronic component mounted to the wiring substrate, an electrode terminal of the first electronic component connected to the first conductor portion through the first opening;
a second electronic component stacked on the first electronic component via an adhesive layer;
a first resin layer between the protective film and the first electronic component; and
a second resin layer between the protective film and the adhesive layer, the second resin layer being outside the first electronic component in a plan view.

2. The semiconductor device according to claim 1, wherein the adhesive layer extends from the second electronic component towards the wiring substrate to a position that is a same distance from the protective layer as the first electronic component.

3. The semiconductor device according to claim 1, wherein the wherein the adhesive layer is a die attached film.

4. The semiconductor device according to claim 1, wherein
the adhesive layer comprises an acrylate resin material,
the first resin layer is an epoxy-based resin, and
the second resin layer is an epoxy-based resin.

5. The semiconductor device according to claim 1, wherein the second resin layer includes a portion extending beyond the adhesive layer in a plan view.

6. The semiconductor device according to claim 1, wherein the first resin layer fills a portion of the first opening.

7. The semiconductor device according to claim 1, wherein the second resin layer fills a portion of the second opening.

8. The semiconductor device according to claim 1, wherein the first resin layer and the second resin layer are formed from a same resin material.

9. The semiconductor device according to claim 1, wherein the first resin layer and the second resin layer have different compositions.

10. The semiconductor device according to claim 1, wherein a portion of the second resin layer covers an outer edge of the first electronic component.

11. The semiconductor device according to claim 1, wherein a portion of the second resin layer is on an upper surface of the first electronic component.

12. The semiconductor device according to claim 1, wherein the second resin layer includes a ridge portion at position between an outer edge of the first electronic component and an outer edge of the adhesive layer.

13. A method for manufacturing a semiconductor device, the method comprising:
mounting a first electronic component to a wiring substrate by connecting an electrode terminal of the first electronic component to a first conductor portion of the wiring substrate through an opening in a protective layer on the wiring substrate;
after the mounting, forming a first resin layer between the first electronic component and the wiring substrate by placing a first uncured resin material along an outer edge of the first electronic component and letting the first uncured resin material fill in a space between the first electronic component and the wiring substrate;
after placing the first uncured resin material along the outer edge of the first electronic component, forming a second resin layer on the wiring substrate by placing a second uncured resin material on the wiring substrate at positions surrounding the first electronic component; and
after placing the second uncured resin material on the wiring substrate, attaching a second electronic component to the first electronic component with an adhesive film, the adhesive film extending beyond the outer edge of the first electronic component in plan view.

14. The method according to claim 13, wherein the first and second uncured resin materials contact each other before thermal curing.

15. The method according to claim 13, wherein the second uncured resin material is cured before the attaching of the second electronic component.

16. The method according to claim 13, wherein the first and second uncured resin material have different compositions.

17. The method according to claim 13, wherein at least one of the first and second resin layers is between each portion of the protective layer and the adhesive film.

18. The method according to claim 13, wherein the first and second resin layers are epoxy-based resins.

19. The method according to claim 13, wherein the adhesive film is a die attached film.

20. The method according to claim 13, wherein the first electronic component is mounted to the wiring substrate by a flip-chip bonding method.
